(19) United States
(12) Patent Application Publication
(10) Pub. No.: US 2008/0157056 A1
(43) Pub. Date: Jul. 3, 2008

(54) Manufacturing method of poly-wavelength light-emitting diode of utilizing nano-crystals and the light-emitting device therefor

(76) Inventors: Dong-Ming Yeh, Hisnchu City (TW); Horng-Shyang Chen, Fongshan City (TW); Chih-Feng Lu, Wang-an Township (TW); Chi-Feng Huang, Taoyuan City (TW); Wen-Yu Shiao, Wurih Township (TW); Jian-Jang Huang, Taipei City (TW); Yen-Cheng Lu, Banciao City (TW); Chih-Chung Yang, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/819,169

(22) Filed: Jun. 26, 2007

(30) Foreign Application Priority Data
Oct. 5, 2006 (TW) 095137177

(51) Int. Cl. H01L 33/00

(52) U.S. Cl. 257/13; 438/35; 257/E33.008

(57) ABSTRACT

A producing method of poly-wavelength light-emitting diode of utilizing nano-crystals and the light-emitting device thereof includes growing and processing a multiple-quantum-well layer based on stacking the mixture of at least two kinds of quantum wells to produce a two-wavelength light-emitting diode. Then, attaching nano-crystals on the two-wavelength light-emitting diode to transfer one of the wavelengths of the two-wavelength light-emitting diode to produce a poly-wavelength light-emitting diode. The device of the present invention can emit blue, green and red lights to produce white light.

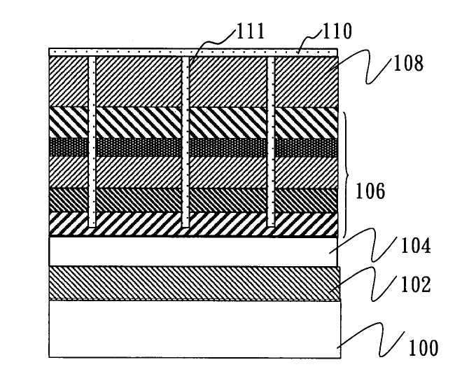

### FIELD OF THE INVENTION

The present invention relates to a light-emitting diode, and more particularly to a manufacturing method of poly-wavelength light-emitting diode of utilizing nano-crystals and the light-emitting devices.

### BACKGROUND OF THE INVENTION

Recently, because of the application of solid-state-lighting and backlighting of liquid-crystal display, the development of white-light light-emitting devices has attracted much attention. Generally speaking, the development of white-light light-emitting diode focuses on converting blue or violet photon emitted from a single-color light-emitting diode into long-wavelength light by using phosphor, and the long-wavelength light mixes with the blue or violet light to generate white light. However, using phosphors to produce white light emission results in lower efficiency, complicated process and the environment problem. Hence, how to produce a phosphor-free white-light light-emitting diode becomes important.

In the development of white light emission for energy-saving solid-state lighting and backlighting of liquid-crystal display, the light-emitting diode based on the GaN-related compounds is an important subject. Though high-efficiency blue and green nitride-based LEDs are quite mature, the yellow or red light-emitting diode are not good enough. Recently, the red light-emitting diode based on nitrides has been reported, but the quantum efficiency or the manufacturing process of the red light-emitting diode require more efforts.

To overcome the foregoing shortcomings, the inventor(s) of the present invention based on years of experience in the related field to conduct extensive researches and experiments, and finally invented a manufacturing method of poly-wavelength light-emitting diode of utilizing nano-crystals and the light-emitting device therefore, as a method or a basis for resolving the foregoing drawbacks.

### SUMMARY OF THE INVENTION

The primary objective of the present invention is to provide a manufacturing method of poly-wavelength light-emitting diode utilizing nano-crystals, the light-emitting diode can emit blue, green, and red lights and mix these light to generate white light.

Another objective of the invention is to provide a light-emitting device with two wavelengths or poly wavelengths utilizing nano-crystals. The nano-crystals are arranged on a single-wavelength or poly-wavelength light-emitting diode to produce another wavelength of light.

To achieve the foregoing objectives, the manufacturing method of the poly-wavelength light-emitting diode utilizing nano-crystals comprises the following steps: while growing a thin film, forming a multiple-quantum-well layer by stacking at least two kinds of quantum wells to produce a two-wavelength light-emitting diode; arranging a plurality of nano-crystals on the two-wavelength light-emitting diode to convert one of the wavelengths of the two wavelengths to produce the poly-wavelength light-emitting diode.

In addition, the invention provides a light-emitting device with a poly-wavelength light-emitting diode utilizing nano-crystals, the light-emitting device comprises a single-wavelength or a poly-wavelength light-emitting diode and a nano-crystals layer. The nano-crystal layer is deposited on the single-wavelength or the poly-wavelength light-emitting diode, that to produce another wavelength.

Comparing to a light-emitting diode fabricated with single quantum well, the foregoing manufacturing method that produces the two-wavelength light-emitting diode by stacking two kinds of quantum well results in small difference in crystal structure and electrical characteristics. The nano-crystals are deposited on the two-wavelength light-emitting diode to produce another wavelength of light, and the light-emitting diode can mix the blue, green and red lights to generate white light.

The light-emitting device in accordance with the present invention comprises a nano-crystal layer which is arranged on the single-wavelength or poly-wavelength light-emitting diode to convert one of the wavelengths to another wavelength for generating another color of light.

To make it easier for our examiner to understand the objective of the invention, its structure, innovative features, and performance, we use preferred embodiments together with the attached drawings for the detailed description of the invention.

### BRIEF DESCRIPTION OF THE DRAWINGS

The FIGURE is a structural diagram view of blue/red two-wavelength light emitting device of the present invention.

### DETAILED DESCRIPTION OF THE PREFERRED EMBODIMENTS

For simplicity, the same symbol or label is used for the same element for the description of a preferred embodiment of a manufacturing method of poly-wavelength light-emitting device utilizing nano-crystals and light-emitting device therefore in accordance with the present invention.

The manufacturing method of a poly-wavelength light-emitting diode of utilizing nano-crystals in accordance with the present invention comprises the following steps: while growing a thin film, forming a multiple-quantum-well layer by stacking at least two kinds of InGaN/GaN quantum well to produce a two-wavelength light-emitting diode; and arranging nano-crystals on the two-wavelength light-emitting diode to convert one of the wavelengths of the two-wavelength light-emitting diode to produce a poly-wavelength light-emitting device. The poly-wavelength light-emitting device can emit blue, green and red lights to produce white light.

The foregoing two-wavelength light-emitting diode further comprises a plurality of holes for filling the nano-crystals. If the side-wall area of the holes is larger, the contrast intensity between the converted wavelengths and non-converted wavelengths is higher. The depth of the holes can reach to the multiple-quantum-well layer, thus the nano-crystals can directly contact the multiple quantum wells and result in a more efficient energy transfer and a more efficient absorption-reemission process.

The foregoing nano-crystals include the semiconductor of the II-VI group, such as CdSe/ZnS nano-crystals.

The process for manufacturing the quantum well layer will be illustrated in details as the following. The invention uses the metalorganic Chemical Vapor Deposition (MOCVD) technique to grow the epitaxial structure of a blue/green two-wavelength light-emitting diode, wherein the growth procedure includes the following steps: After the growth of a 25-nm nucleation layer (grown at 535° C.), a 2-μm n-GaN is deposited at 1070° C. with doped silicon concentration at 5×10¹⁸ cm⁻³. Afterward, the quantum-well structure is formed based on two quantum well growth conditions: (1) temperature at 690° C., wafer carrier rotation speed at 750 rpm, and gas flow rates at 3000 sccm for nitrogen, and 3000 sccm for ammonia; and (2) temperature at 710° C., wafer carrier rotation speed at 1500 rpm, and gas flow rates at 1000 sccm for nitrogen and 1500 sccm for ammonia. The two growth conditions are designed for growing the quantum well which emits green or blue light. All the well thickness is about 3 nm. Under the different growth conditions, the indium compositions are different, leading to the emission of the different colors. Either purely blue or green light-emitting diode can be obtained by growing a quantum-well structure based on one of the aforesaid conditions. In the mixed quantum-well structure from the bottom to top includes the quantum wells for emitting green/blue/blue/green colors.

The relative electroluminescence intensity of the two colors produced by the two-wavelength LED depends upon the injection current because the injection current controls the hole concentration distribution among the quantum wells. The forgoing blue/green two-wavelength light-emitting diode is taken as an example. When low injection current is injected, the quantum well for emitting green light at the top of the LED dominates the emission. When injection current increases, the quantum well for emitting blue light next to the top one dominates the emission.

The two-wavelength light-emitting diode or the poly-wavelength light emitting diode made by utilizing nano-crystals includes a step of depositing a nano-crystal layer on the single-wavelength or the poly-wavelength light-emitting diode to produce another light wavelength. This light wavelength is related to the particle size of the nano-crystals. Therefore, the Commission International de I'Eclairage (CIE) coordinates of the mixed light with poly-wavelength can be controlled by changing the particle size of the nano-crystals.

The forgoing single-wavelength or the poly-wavelength light-emitting diode further includes a plurality of apertures for filling with the nano-crystals. The side-wall area of the apertures controls the color contrast intensity. The depth of aperture can reach the active layer of the single-wavelength light-emitting diode or the poly-wavelength light-emitting diode.

The forgoing poly-wavelength light-emitting diode includes a multiple-quantum-well layer structure by stacking a mixture of at least two different kinds of quantum wells.

The foregoing nano-crystals includes the II-VI compound semiconductors, and the nano-crystals include CdSe/ZnS.

The FIGURE is a structural diagram of a blue/red two-wavelength light emitting device of the present invention. As shown in the FIGURE, a blue light multiple-quantum-well structure is grown on a sapphire substrate 100 by using MOCVD. The light-emitting diode sequentially includes a 25 nm GaN buffer layer 102, 2-μm Si-doped GaN layer 104, five periods of InGaN/GaN (3 nm/18 nm) quantum wells 106 and 80 nm Mg-doped GaN layer 108. Holes 111 are then formed on the light-emitting diode by using photolithography and inductively-coupled plasma reactive ion etching, and etching depth is 1.2 μm. Namely, the active layer of the multiple quantum-wells in the apertures 111 is removed. The apertures 111 are filled with toluene solution of CdSe/ZnS nano-crystals. A droplet of the solution of the nano-crystals is deposited on each light emitting diode with the same volume. Therefore, the numbers of the nano-crystals on different light-emitting diode for comparison are supposed to be the same. Afterward, the light-emitting diode is slightly shaken, and each aperture is uniformly filled with the solution of the nano-crystals, and there is a uniform nano-crystal layer 110 on each light-emitting diode. In the embodiment, the diameter of the CdSe/ZnS particles is about 4 nm, and the thickness of the ZnS shell layer is 0.2 nm. The emission wavelength of the blue light-emitting diode is about 450 nm. The blue photon at 450 nm emission wavelength emitted by the multiple-quantum-well-layer is absorbed by the nano-crystals to emit red light at 590 nm in wavelength.

The method of manufacturing poly-wavelength light-emitting diode by using nano-crystals is used to form the multiple-quantum-well structure layer by stacking a mixture of two kinds of quantum well. When the light-emitting diode of a mixed multiple-quantum-well-structure layer is compared with a light-emitting diode made of an individual kind of quantum well, there is no major difference in the crystal structure and basic electrical characteristics. The invention further deposits the nano-crystals on the two-wavelength light-emitting diode to produce another wavelength, such that the poly-wavelength light-emitting device for emitting blue, green and red light of three wavelengths can be made to mix the aforesaid colors to generate white light.

By comparing with the prior art, the invention can overcome the shortcomings of complex process, patent restriction and environmental protection. The phosphor-free, single-chip, all-semiconductor, white-light light-emitting diode can be therefore made.

The two-wavelength or poly-wavelength light-emitting devices made by using the nano-crystals is to deposit the nano-crystals on the single-wavelength light-emitting diode or the poly-wavelength light-emitting diode, and one of the wavelength components of the single-wavelength light-emitting diode or the poly-wavelength light-emitting diode is transferred into another wavelength so as to generate another color. Accordingly, the single-wavelength light-emitting diode or the poly-wavelength light-emitting diode is made to become the two-wavelength or poly-wavelength light-emitting device.

The light-emitting diode of the invention has a plurality of apertures for filling with the nano-crystals. By controlling the size of the apertures, when the side-wall area of the apertures is bigger, the intensity ratio of colors between a portion of transferred wavelength and a portion of untransformed wavelength is higher, thereby controlling the intensity ratio between colors.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A manufacturing method of a poly-wavelength light-emitting diode of utilizing nano-crystals, comprising:
forming a multiple-quantum-well layer structure to produce a two-wavelength light-emitting diode by stacking at least two kinds of InGaN/GaN quantum well; and
arranging a plurality of nano-crystals on said two-wavelength light-emitting diode to convert one of the wavelengths of said two-wavelength light-emitting diode to produce a poly-wavelength diode;
wherein said nano-crystals include nano-size semiconductor particle structures of III-V group, II-VI group or I-VII group.

2. The manufacturing method of claim 1, wherein the relative electroluminescence intensity of the two colors light generated by said two-wavelength light-emitting diode depends on injection current.

3. The manufacturing method of claim 1, wherein said two-wavelength light-emitting diode further comprises a plurality of holes for filling said nano-crystals.

4. The manufacturing method of claim 3, wherein the depth of said holes can reach to said multiple-quantum-well layer.

5. The manufacturing method of claim 3, wherein when the side-wall area of the apertures is bigger, the intensity ratio of colors between a portion of transferred wavelength and a portion of untransformed wavelength is higher.

6. The method of claim 1, wherein said nano-crystals include CdSe/ZnS.

7. The method of claim 1, wherein the transferred wavelength portion of the nano-crystals relates to the particle size of the nano-crystals, and CIE coordinate of the mixed light with said poly-wavelength is controlled by changing the particle size of the nano-crystals.

8. A light-emitting element of a two-wavelength light emitting diode or a poly-wavelength light-emitting diode made by using nano-crystals, comprising:
a single-wavelength light-emitting diode or a poly-wavelength light-emitting diode; and
a nano-crystal layer deposited on said single-wavelength or said poly-wavelength light-emitting diode;
wherein said nano-crystals include semiconductor nano-particles of III-V group, II-VI group or I-VII group.

9. The light-emitting element of claim 8, wherein said single-wavelength or said poly-wavelength light-emitting diode further includes a plurality of apertures for filling with said nano-crystals of said nano-crystals layer.

10. The light-emitting element of claim 9, wherein the depth of said plurality of apertures reaches an active layer of said single-wavelength light-emitting diode or said poly-wavelength light-emitting diode.

11. The light-emitting element of claim 8, wherein said poly-wavelength light-emitting diode includes a multiple-quantum-well layer structure by stacking a mixture of at least two kinds of InGaN/GaN quantum wells.

12. The light emitting element of claim 8, wherein said nano-crystals include CdSe/ZnS.
